(19) United States
(12) Patent Application Publication
(10) Pub. No.: US 2009/0020878 A1
(43) Pub. Date: Jan. 22, 2009

(54) SEMICONDUCTOR PACKAGES AND METHODS OF FABRICATING THE SAME

(75) Inventors: Seung-Kwan RYU, Gyeonggi-do (KR); Hee-Kook CHOI, Seoul (KR); Sung-Min SIM, Gyeonggi-do (KR); Dong-Hyeon JANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/014,600

(22) Filed: Jan. 15, 2008

(30) Foreign Application Priority Data
Jan. 25, 2007 (KR) 10-2007-8031

(51) Int. Cl. H01L 21/768; H01L 23/52

(52) U.S. Cl. 257/773; 438/618; 257/E23.141; 257/E21.59

(57) ABSTRACT

A semiconductor package is provided. The semiconductor package includes a semiconductor device having a bonding pad and an interlayer insulating layer disposed on the semiconductor device. The interlayer insulating layer has an opening which exposes the bonding pad and has at least one cavity therein. A redistributed interconnection is disposed on the interlayer insulating layer and electrically connected to the exposed bonding pad. The redistributed interconnection is disposed over the cavity. A method of fabricating the semiconductor package is also provided.

### CROSS-REFERENCE TO RELATED APPLICATION

This U.S. non-provisional patent application claims priority under 35 U.S.C. § 119 to Korean Patent Application No. 10-2007-8031 filed on Jan. 25, 2007, the entire contents of which are hereby incorporated by reference.

### BACKGROUND

1. Technical Field

The present invention relates to semiconductor packages and methods of fabricating the same. More particularly, the present invention relates to semiconductor packages have a redistributed interconnection and methods of fabricating the semiconductor packages.

2. Description of the Related Art

In the semiconductor industry, many technologies have been developed to scale down the size of semiconductor devices. Accordingly, there has been significant demand for reducing the size of semiconductor packages that encapsulate the semiconductor devices because the semiconductor packages are employed in small computers, portable electronic systems and the like. Along these lines, various semiconductor packages such as fine pitch ball grid array (FBGA) packages or chip scale packages (CSP) have been developed to increase the number of pins of the semiconductor packages within the limited sizes thereof.

The semiconductor packages such as the FBGA packages or the CSPs may have some physical advantages, including the size and weight, as compared to conventional plastic packages. However, the FBGA packages or the CSPs may still exhibit some disadvantages in terms of reliability and fabrication cost as compared to the conventional plastic packages. In particular, micro ball grid array (μBGA) packages of the typical CSPs may exhibit excellent characteristics as compared to the FBGA packages or the typical CSPs, however the μBGA packages may still possess some disadvantages in terms of reliability and fabrication cost.

In recent years, a novel semiconductor package such as a wafer level chip scale package (WL-CSP) has been proposed in response to the above disadvantages. The WL-CSP utilizes a redistribution scheme or a rerouting scheme of bonding pads of the semiconductor device.

The WL-CSP may include so-called “redistributed” metal interconnections. The redistributed metal interconnections are provided to electrically connect the bonding pads to redistributed pads which are spatially separated from the bonding pads. The redistributed pads correspond to pads which are in direct contact with solder balls, solder bumps or bonding wires for a package.

FIG. 1 is a cross sectional view illustrating a conventional WL-CSP.

Referring to FIG. 1, the conventional WL-CSP comprises a semiconductor device 10 having a metal interconnection 11 and a bonding pad 12. An interlayer insulating layer 14 is disposed on the semiconductor device 10 including the bonding pad 12. The bonding pad 12 is exposed by a pad window which penetrates the interlayer insulating layer 14. A redistributed interconnection 22 is disposed on the interlayer insulating layer 14 and is connected to the bonding pad 12 through the pad window. An under barrier metal (UBM) 20a is disposed under the redistributed interconnection 22, thereby directly contacting the bonding pad 12 and the interlayer insulating layer 14. The redistributed interconnection 22 and the interlayer insulating layer 14 are covered with a passivation layer 24. A portion of the redistributed interconnection 22 is exposed by an opening which penetrates the passivation layer 24. The exposed portion of the redistributed interconnection 22 corresponds to a redistributed pad.

According to the conventional WL-CSP described above, the metal interconnection 11 may overlap with the redistributed interconnection 22. Thus, parasitic capacitance may exist between the metal interconnection 11 and the redistributed interconnection 22. The parasitic capacitance may degrade the electrical characteristics of the semiconductor package. In particular, as the integration density, the operation speed and the performance of the semiconductor device become higher, the parasitic capacitance may increase so as to significantly reduce the noise margin of the semiconductor package.

The present invention addresses these and other disadvantages of the conventional art.

### SUMMARY

Exemplary embodiments of the present invention are directed to a semiconductor package and a method of fabricating the same. In an exemplary embodiment, the semiconductor package includes a semiconductor device having a bonding pad and an interlayer insulating layer disposed on the semiconductor device. The interlayer insulating layer has an opening which exposes the bonding pad and has at least one cavity therein. A redistributed interconnection i-disposed on the interlayer insulating layer and electrically connected to the exposed bonding pad. The redistributed interconnection is disposed over the cavity.

### BRIEF DESCRIPTION OF THE DRAWINGS

FIG. 1 is a cross sectional view illustrating a conventional semiconductor package.

FIG. 2 is a plan view illustrating a semiconductor package according to an embodiment of the present invention.

FIG. 3 is an enlarged plan view of a portion “A” of FIG. 2.

FIGS. 4A and 4B are cross sectional views taken along the lines I-I′ and II-II′ of FIG. 3, respectively.

FIGS. 5A to 5H are cross sectional views taken along the line I-I′ of FIG. 3 illustrating methods of fabricating a semiconductor device according to an embodiment of the present invention.

FIGS. 6A to 6H are cross sectional views taken along the line II-II′ of FIG. 3 illustrating methods of fabricating a semiconductor device according to an embodiment of the present invention.

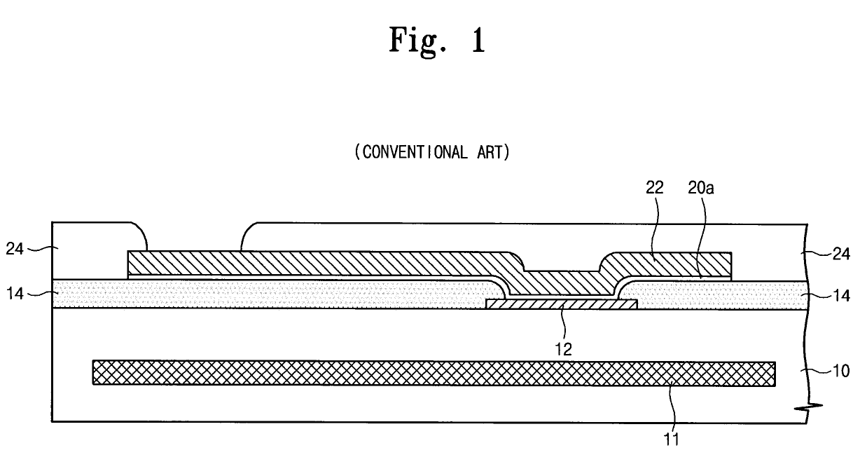

### DETAILED DESCRIPTION

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like reference numbers refer to like elements throughout.

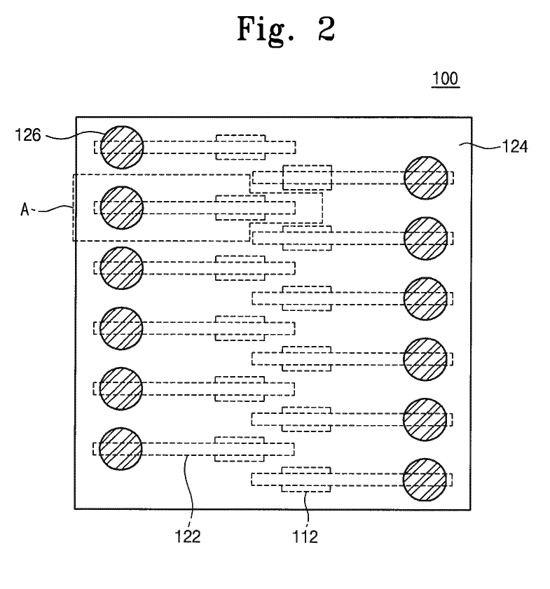

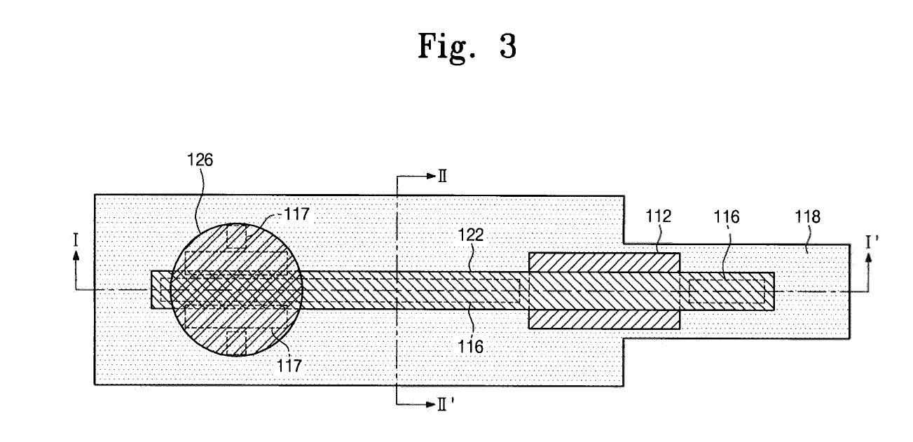

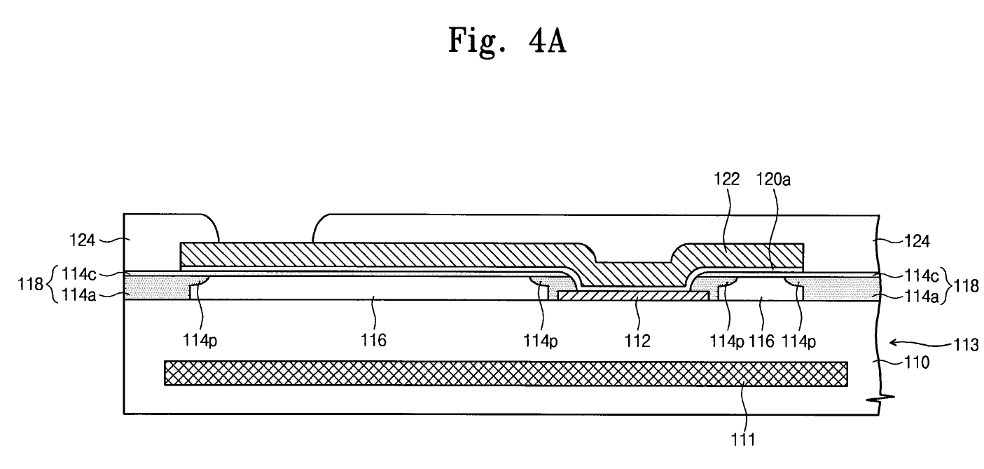

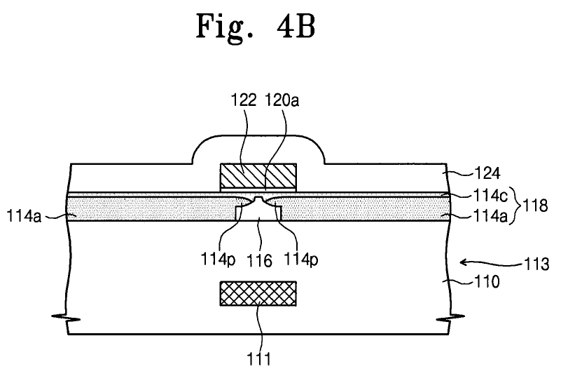

FIG. 2 is a plan view illustrating a semiconductor package according to an embodiment of the present invention, and FIG. 3 is an enlarged plan view of a portion “A” of FIG. 2. Further, FIGS. 4A and 4B are cross sectional views taken along the lines I-I′ and II-II′ of FIG. 3, respectively.

Referring to FIGS. 2, 3, 4A and 4B, the semiconductor package 100 may comprise a semiconductor device 113, an interlayer insulating layer 118, a plurality of redistributed interconnections 122, a passivation layer 124 and a plurality of connection members 126.

The semiconductor device 113 may include a semiconductor substrate 110, metal interconnections 111 in or on the semiconductor substrate 110, and bonding pads 112 on the semiconductor substrate 110. The semiconductor device 113 may further include a chip passivation layer (not shown) covering the bonding pads 112 and the semiconductor substrate 110. When the chip passivation layer is provided, each of the bonding pads 112 may be exposed by one of a plurality of pad windows which penetrate the chip passivation layer. The bonding pads 112 may electrically connect internal circuits of the semiconductor device 113 to external circuits such as a system board or the like. The bonding pads 112 may be formed of a metal layer such as an aluminum layer.

The interlayer insulating layer 118 may be disposed on the semiconductor device 113 including the bonding pads 112. When the chip passivation layer is provided, the interlayer insulating layer 118 is disposed on the chip passivation layer. The interlayer insulating layer 118 may comprise a first interlayer insulating layer 114a and a second interlayer insulating layer 114c which are sequentially stacked. The first interlayer insulating layer 114a may have cavities 116 therein, and the cavities 116 are covered with the second interlayer insulating layer 114c. The first interlayer insulating layer 114a may further include protrusions 114p to reduce upper widths of the cavities 116.

The first interlayer insulating layer 114a may comprise a negative type photosensitive material layer. The negative type photosensitive material layer may comprise at least one of a photoresist layer, a photosensitive polyimide (PSPI) layer and a polybenzoxazole (PBO) layer. The second interlayer insulating layer 114c may also comprise at least one of a photoresist layer, a photosensitive polyimide (PSPI) layer and a polybenzoxazole (PBO) layer. Therefore, the second interlayer insulating layer 114c may be the same material layer as the first interlayer insulating layer 114a.

The redistributed interconnections 122 may be disposed on the interlayer insulating layer 118 and may be electrically connected to the bonding pads 112 through openings which penetrate the interlayer insulating layer 118. The redistributed interconnections 122 may connect the bonding pads 112 to the external circuits such as the system board or the like. Each of the redistributed interconnections 122 may comprise at least one of gold, silver, copper, nickel, platinum and a metal-alloy thereof. That is, the redistributed interconnections 122 may be a single metal layer or a single metal alloy layer. In an embodiment, the redistributed interconnections 122 may comprise a copper layer.

Under barrier metal (UBM) patterns 120a may be further disposed under the redistributed interconnections 122, respectively. In this case, the UBM patterns 120a may be in direct contact with the interlayer insulating layer 118 and the bonding pads 112. Each of the UBM patterns 120a may be a single layer which comprises one of a gold layer, a silver layer, a copper layer, a nickel layer, a platinum layer, a titanium layer, a titanium tungsten layer and a metal-alloy layer thereof. Alternatively, each of the UBM patterns 120a may be a double layer which comprises two layers from a group including a gold layer, a silver layer, a copper layer, a nickel layer, a platinum layer, a titanium layer, a titanium tungsten layer and a metal-alloy layer thereof.

The passivation layer 124 may be disposed on the redistributed interconnections 122 and the interlayer insulating layer 118. At least a portion of each of the redistributed interconnections 122 may be exposed by openings which penetrate the passivation layer 124, as shown in FIG. 4A. The passivation layer 124 may comprise a photo solder resist (PSR) layer or a photosensitive polyimide (PSPI) layer.

The connection members 126 may be provided on the exposed portions of the redistributed interconnections 122. Thus, the exposed portions of the redistributed interconnections 122 may be electrically connected to the external circuits such as the system board or the like through the connection members 126. The connection members 126 may be, for example, solder balls, solder bumps or bonding wires.

According to the aforementioned embodiments, the semiconductor package 100 may be configured to have the connection members 126 which are provided on the exposed portions of the redistributed interconnections 122. Therefore, the exposed portions of the redistributed interconnections 122 may act as redistributed pads which correspond to bonding pads 112 of the semiconductor package 100. In addition, the cavities 116 are located under the redistributed interconnections 122, as illustrated in FIG. 4A. That is, the cavities 116 may overlap with the redistributed interconnections 122.

Further, when the connection members 126 are solder balls, the interlayer insulating layer 118 may additionally have other cavities 117 which are provided under the solder balls as illustrated in FIG. 3. The other cavities 117 may have a line shaped configuration. For example, the other cavities 117 may have a grid-shaped configuration, radiation-shaped configuration or a spiral shaped configuration. Alternatively, the other cavities 117 may have a circular shaped configuration, a regular triangle-shaped configuration or a quadrangle-shaped configuration.

The cavities 116 and 117 may be filled with air which has a lower dielectric constant than that of the interlayer insulating layer 118. Thus, the cavities 116 and 117 may reduce the parasitic capacitance between the metal interconnections 111 and the redistributed interconnections 122.

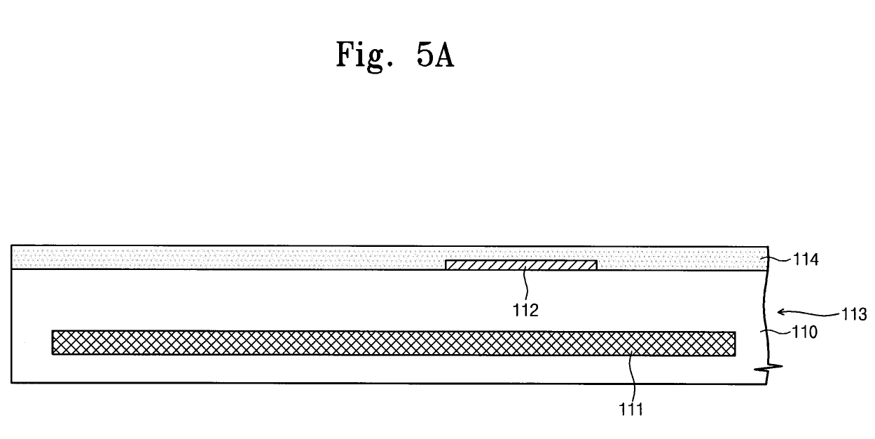

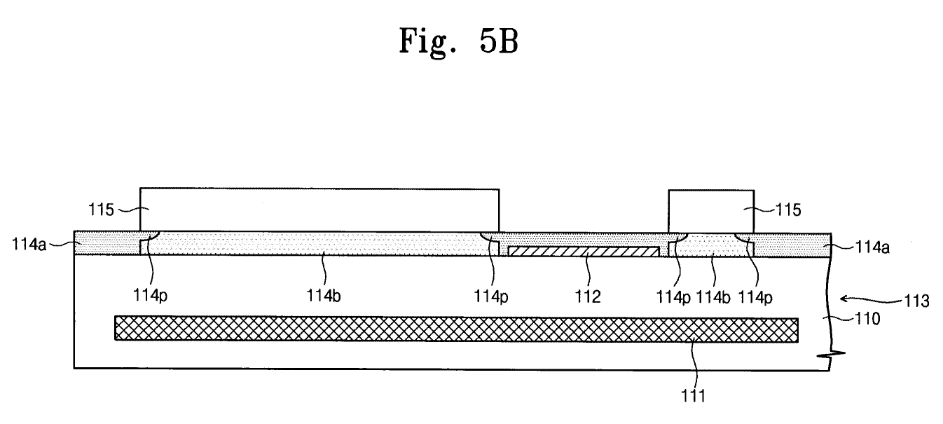

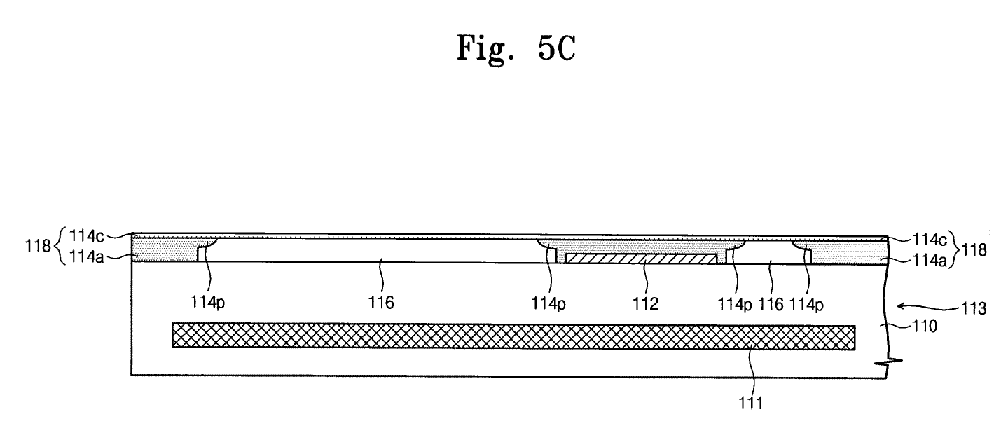

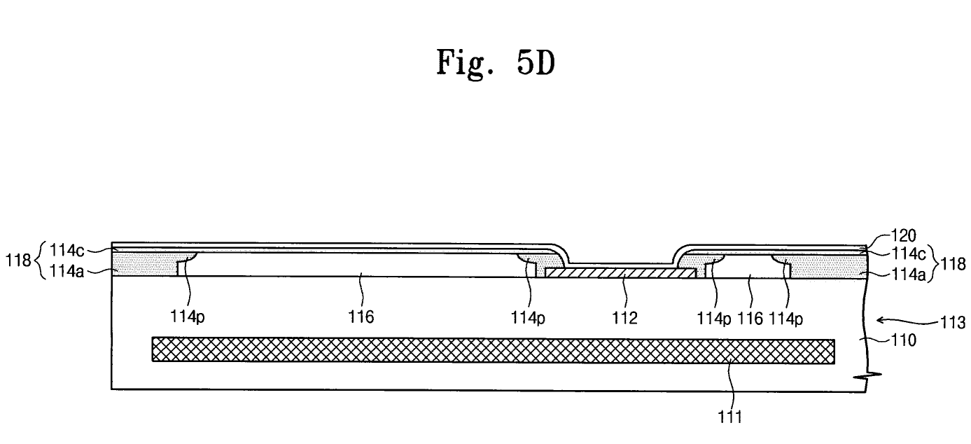

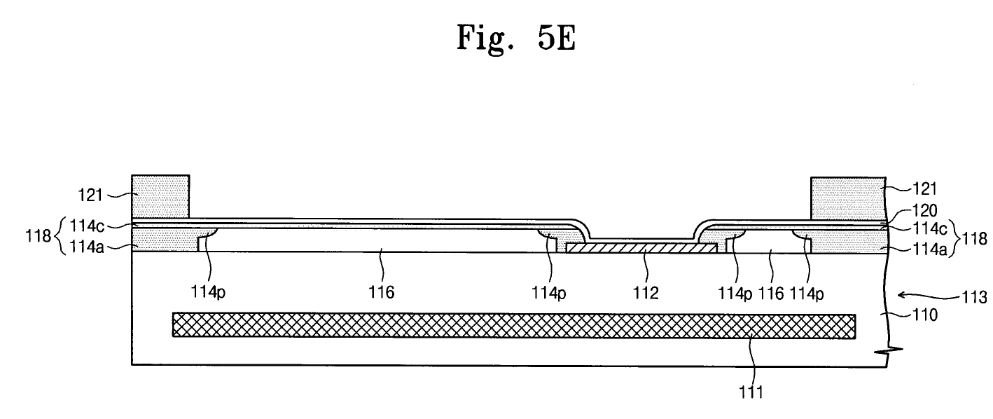

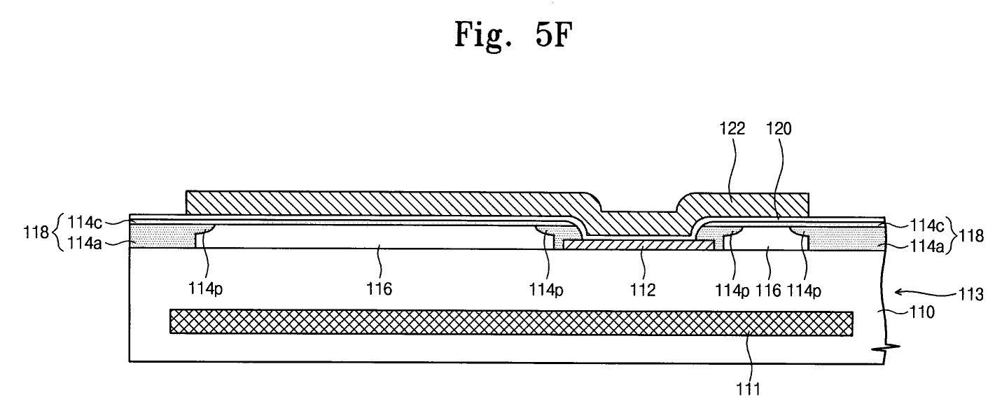

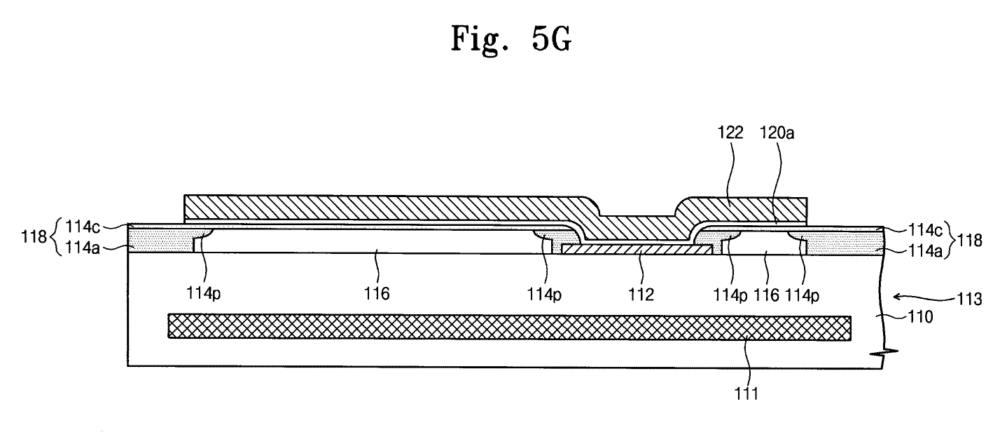

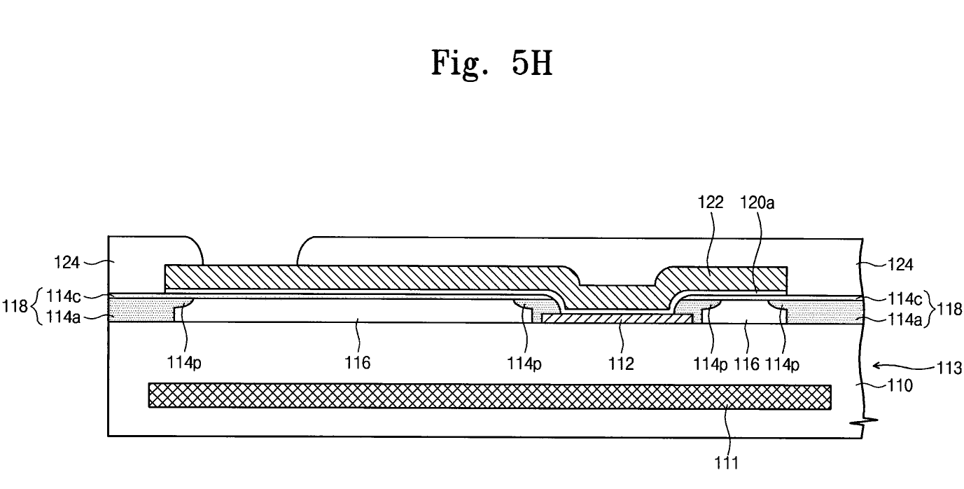

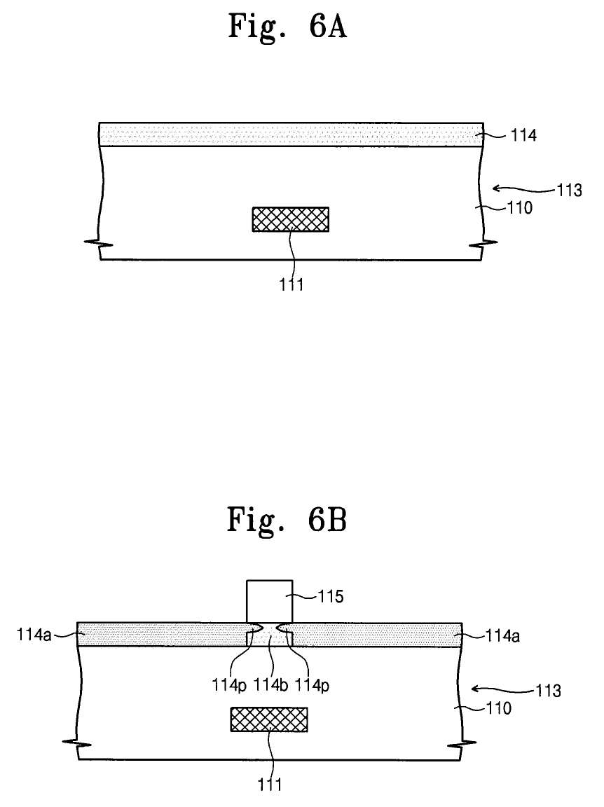

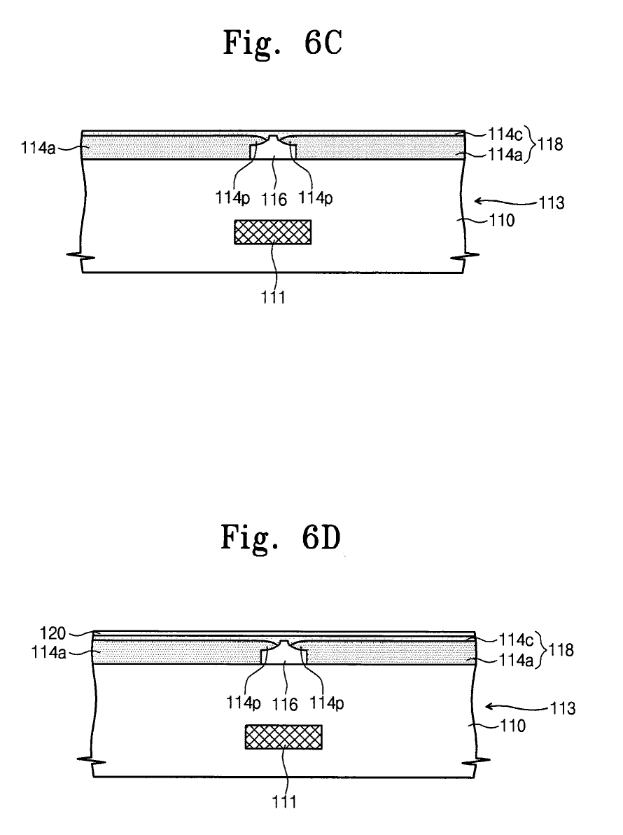

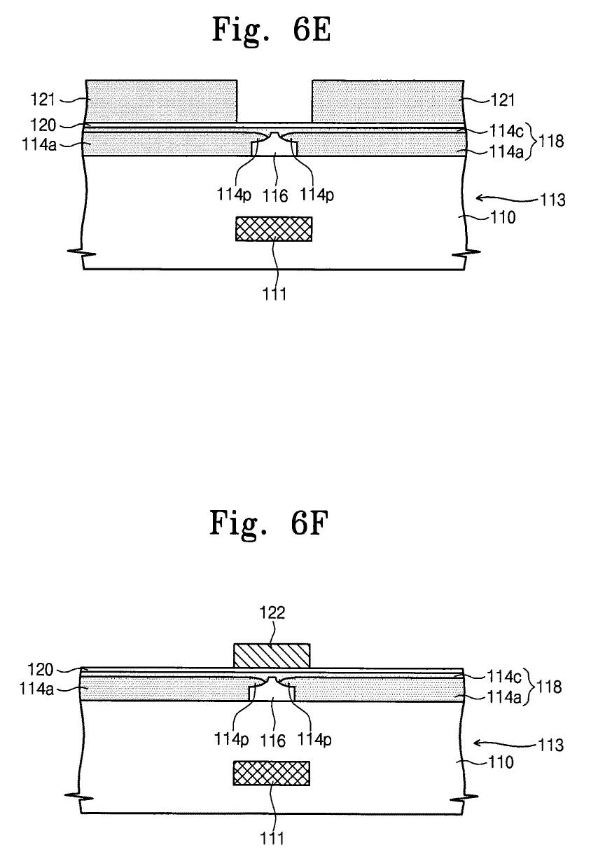

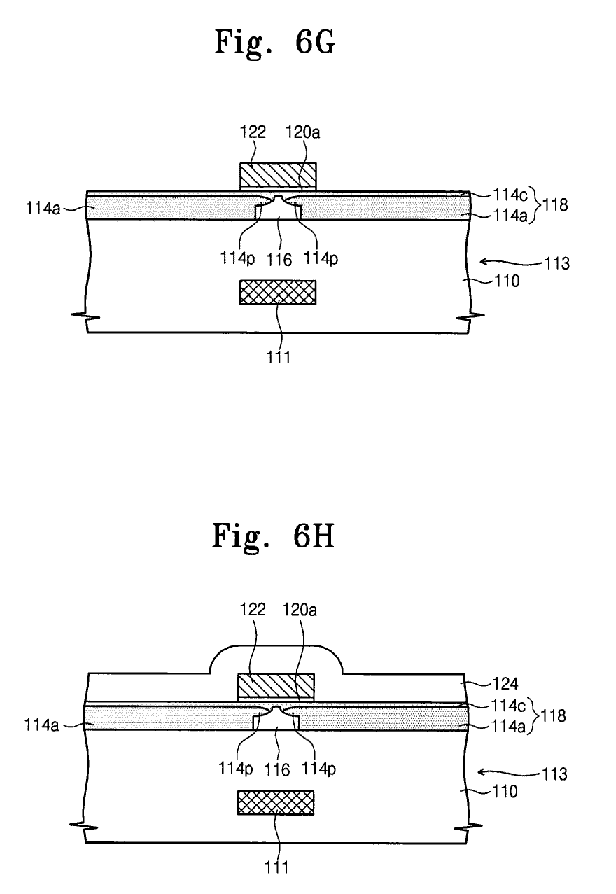

FIGS. 5A to 5H are cross sectional views taken along the line I-I′ of FIG. 3 illustrating methods of fabricating a semiconductor package according to an embodiment of the present invention, and FIGS. 6A to 6H are cross sectional views taken along the line II-II′ of FIG. 3 illustrating methods of fabricating a semiconductor package according to an embodiment of the present invention. The present embodiment will be described in conjunction with a wafer level chip scale package (WL-CSP). However, a person of ordinary skill in the art will appreciate that the present embodiment is also applicable to other types of semiconductor packages.

Referring to FIGS. 5A, 5B, 6A and 6B, a plurality of metal interconnections 111 may be formed in or on a semiconductor substrate 110, and a plurality of bonding pads 112 may be formed on the semiconductor substrate 110 including the metal interconnections 111. A first interlayer insulating layer 114 is formed on the semiconductor substrate 110 and the bonding pads 112. The first interlayer insulating layer 114 may comprise a negative type photosensitive material. For example, the first interlayer insulating layer 114 may be formed of at least one selected from the group consisting of a negative photoresist layer, a negative photosensitive polyimide (PSPI) layer and a negative polybenzoxazole (PBO) layer. A chip passivation layer (not shown) may be additionally formed on the bonding pads 112 and the semiconductor substrate 110 prior to formation of the first interlayer insulating layer 114. In this case, the bonding pads 112 may be exposed by pad windows which penetrate the chip passivation layer.

A plurality of mask patterns 115 may be formed on predetermined regions of the first interlayer insulating layer 114. An exposure process is then performed using the mask patterns 115 as photo masks, thereby defining unexposed regions 114b of the first interlayer insulating layer 114 under the mask patterns 115 and an exposed region 114a of the first interlayer insulating layer 114 adjacent to the unexposed regions 114b. In the present embodiment, the first interlayer insulating layer 114 on the bonding pads 112 may be exposed during the exposure process. Thus, the exposed region 114a may be formed on the bonding pads 112.

When the exposure energy and the depth of focus are appropriately adjusted during the exposure process, exposure light may be irradiated into the first interlayer insulating layer 114 underneath edges of the mask patterns 115 during the exposure process. In this case, protrusions 114p, which extend from the exposed region 114a, may be formed below the edges of the mask patterns 115. The protrusions 114p may reduce upper widths of the unexposed regions 114b. Further, the length of the protrusions 114p along a direction parallel to the bottom surface of the mask patterns 115 may be changed according to the exposure energy of the exposure process. For example, when the exposure energy of the exposure process increases, the length of the protrusions 114p may also increase. In this case, the upper width of the unexposed regions 114b may correspondingly decrease.

Referring to FIGS. 5C and 6C, the mask patterns 115 are removed after the exposure process, and a development process may be performed after removal of the mask patterns 115. When the first interlayer insulating layer 114 is formed of the negative type photosensitive material layer as describe above, the unexposed regions 114b may be removed during the development process to form cavities 116. Therefore, the exposed region 114a may remain to act as the first interlayer insulating layer 114. In the event that the protrusions 114p are formed, an upper width of each of the cavities 116 may be less than a lower width of the corresponding cavity 116 because of the presence of the protrusions 114p, as shown in FIGS. SC and 6C.

Subsequently, a second interlayer insulating layer 114c may be formed on the first interlayer insulating layer 114a including the cavities 116 therein. The second interlayer insulating layer 114c may also be formed of at least one selected from the group consisting of a negative photoresist layer, a negative photosensitive polyimide (PSPI) layer and a negative polybenzoxazole (PBO) layer. In this case, the second interlayer insulating layer 114c may be formed to cover the cavities 116 and the cavities 116 may not be filled with the second interlayer insulating layer 114c. This is due to the presence of the protrusions 114p. Thus, even though the second interlayer insulating layer 114c is formed on the first interlayer insulating layer 114a, the cavities 116 are not filled by the second interlayer insulating layer 114c. The first and second interlayer insulating layers 114a and 114c constitute an interlayer insulating layer 118. As a result, the cavities 116 may be formed in the interlayer insulating layer 118.

Referring to FIGS. 5D and 6D, the interlayer insulating layer 118 is patterned to form a plurality of openings which expose the bonding pads 112 respectively. When the first and second interlayer insulating layers 114a and 114c are formed of the same material layer, the openings may be formed using a single etch process. An under barrier metal (UBM) layer 120 may be formed on the exposed bonding pads 112 and the interlayer insulating layer 118. The UBM layer 120 may be formed of a single layer which comprises one of a gold layer, a silver layer, a copper layer, a nickel layer, a platinum layer, a titanium layer, a titanium tungsten layer and a metal-alloy layer thereof. Alternatively, the UBM layer 120 may be formed of a double layer which comprises two layers from a group including a gold layer, a silver layer, a copper layer, a nickel layer, a platinum layer, a titanium layer, a titanium tungsten layer and a metal-alloy layer thereof. The UBM layer 120 may be formed using a physical vapor deposition (PVD) technique such as a sputtering process or an evaporation process.

Referring to FIGS. 5E, 5F, 6E and 6F, a photoresist pattern 121 may be formed on the UBM layer 120. In this case, the photoresist pattern 121 may be formed to have a plurality of openings. Each of the openings of the photoresist pattern 121 may expose a portion of the UBM layer 120 which overlies one of the bonding pads 112 and at least one of the cavities 116 adjacent to the bonding pad 112, as illustrated in FIGS. 5E and 6E. A plurality of redistributed interconnections 122 may be selectively formed on the exposed portions of the UBM layer 120, respectively. The redistributed interconnections 122 may be formed using an electroplating technique or an electroless plating technique. The redistributed interconnections 122 may be formed of gold, silver, copper, nickel, platinum or a metal-alloy thereof.

The photoresist pattern 121 is removed after formation of the redistributed interconnections 122. As a result, even though one of the redistributed interconnections 122 is formed to overlap with one of the metal interconnections 111, there may be at least one cavity 116 between the redistributed interconnection 122 and the metal interconnection 111 which overlap with each other. The cavities 116 may be filled with air, which has a lower dielectric constant than that of the interlayer insulating layer 118. Thus, parasitic capacitance between the overlapped redistributed interconnection 122 and metal interconnection 111 may be significantly reduced due to the presence of the cavity 116, as compared to the conventional art.

Referring to FIGS. 5G, 5H, 6G and 6H, the UBM layer 120 may be etched using the redistributed interconnections 122 as etching masks. As a result, a plurality of UBM patterns 120a may be formed under the redistributed interconnections 122, respectively. The UBM layer 120 may be etched using a wet etching technique.

A passivation layer 124 may be formed on the interlayer insulating layer 118 and the redistributed interconnections 122. The passivation layer 124 is patterned to form a plurality of openings which expose predetermined portions of the redistributed interconnections 122. The exposed portions of the redistributed interconnections 122 may correspond to redistributed pads. The openings penetrating the passivation layer 124 may be formed so that the redistributed pads are spaced apart from the bonding pad 112 along a direction parallel to an upper surface of the substrate 110.

Connection members (126 of FIG. 2) may be formed on the redistributed pads which are exposed by the openings that penetrate the passivation layer 124. The connection members may be formed of solder balls, solder bumps or bonding wires. When the connection members are formed of the solder balls, other cavities (117 of FIG. 3) may be additionally formed under the solder balls. The other cavities 117 may be formed to have a line shaped configuration. For example, the other cavities 117 may be formed to have a grid-shaped configuration, radiation-shaped configuration or a spiral shaped configuration. Alternatively, the other cavities 117 may be formed to have a circular shaped configuration, a regular triangle-shaped configuration or a quadrangle-shaped configuration.

According to the embodiments described above, at least one cavity is disposed under a redistributed interconnection which is formed over a semiconductor device. Thus, even though the redistributed interconnection may overlap with a metal interconnection formed in the semiconductor device, parasitic capacitance between the overlapped redistributed interconnection and the metal interconnection may be significantly reduced due to the presence of the cavity therebetween, as compared to the conventional art. Hence, the semiconductor package including the redistributed interconnection may exhibit excellent electrical characteristics such as a large noise margin.

In an exemplary embodiment of the present invention, the semiconductor package includes a semiconductor device having a bonding pad and an interlayer insulating layer disposed on the semiconductor device. The interlayer insulating layer defines an opening exposing the bonding pad and includes at least one cavity therein. The cavity may be adjacent to the bonding pad. A redistributed interconnection is disposed on the interlayer insulating layer and is electrically connected to the exposed bonding pad. The redistributed interconnection is disposed over the cavity.

In some embodiments, the interlayer insulating layer may comprise a first interlayer insulating layer having the cavity therein and a second interlayer insulating layer on the first interlayer insulating layer. The first interlayer insulating layer may have a protrusion which extends along a direction parallel to an upper surface of the first interlayer insulating layer to reduce an upper width of the cavity, and the second interlayer insulating layer may be disposed to cover the cavity and the protrusion. The first interlayer insulating layer may comprise a negative type photosensitive material layer. The negative type photosensitive material layer may comprise at least one selected from the group consisting of a photoresist layer, a photosensitive polyimide (PSPI) layer and a polybenzoxazole (PBO) layer. The second interlayer insulating layer may be the same material layer as the first interlayer insulating layer.

In other embodiments, the semiconductor package may further comprise an under barrier metal pattern disposed under the redistributed interconnection. The under barrier metal pattern may be disposed on the interlayer insulating layer and the exposed bonding pad.

In still other embodiments, the semiconductor package may further comprise a passivation layer on the redistributed interconnection and the interlayer insulating layer. The passivation layer may have an opening which exposes a portion of the redistributed interconnection. Moreover, the semiconductor package may further comprise a connection member on the exposed portion of the redistributed interconnection. The connection member may comprise at least one selected from the group consisting of a solder ball, a solder bump or a bonding wire. The interlayer insulating layer may further comprise one or more additional cavities under the connection member. In this case, the additional cavities may have a line-shaped configuration, a circular shaped configuration, a regular triangle-shaped configuration or a quadrangle-shaped configuration.

In another exemplary embodiment, the method of fabricating the semiconductor package includes forming a semiconductor device having a bonding pad and forming an interlayer insulating layer on the semiconductor device. The interlayer insulating layer is formed to have an opening which exposes the bonding pad and to have at least one cavity therein. A redistributed interconnection is disposed on the interlayer insulating layer to overlap with the cavity. The redistributed interconnection is formed to extend onto the exposed bonding pad.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the invention.

What is claimed is:

1. A semiconductor package, comprising:
a semiconductor device having a bonding pad;
an interlayer insulating layer disposed on the semiconductor device, the interlayer insulating layer defining an opening exposing the bonding pad and having at least one cavity therein; and
a redistributed interconnection disposed on the interlayer insulating layer and electrically connected to the exposed bonding pad,
wherein the redistributed interconnection is disposed over the cavity.

2. The semiconductor package as set forth in claim 1, wherein the interlayer insulating layer comprises:
a first interlayer insulating layer having the cavity therein, the first interlayer insulating layer having a protrusion which extends along a direction parallel to an upper surface of the first interlayer insulating layer to reduce an upper width of the cavity; and
a second interlayer insulating layer disposed on the first interlayer insulating layer to cover the cavity and the protrusion.

3. The semiconductor package as set forth in claim 2, wherein the first interlayer insulating layer comprises a negative type photosensitive material layer.

4. The semiconductor package as set forth in claim 3, wherein the negative type photosensitive material layer comprises at least one selected from the group consisting of a photoresist layer, a photosensitive polyimide (PSPI) layer and a polybenzoxazole (PBO) layer.

5. The semiconductor package as set forth in claim 2, wherein the second interlayer insulating layer is the same material layer as the first interlayer insulating layer.

6. The semiconductor package as set forth in claim 1, further comprising an under barrier metal pattern disposed under the redistributed interconnection, wherein the under barrier metal pattern is disposed on the interlayer insulating layer and the exposed bonding pad.

7. The semiconductor package as set forth in claim 1, further comprising a passivation layer on the redistributed interconnection and the interlayer insulating layer, wherein the passivation layer defines an opening exposing a portion of the redistributed interconnection.

8. The semiconductor package as set forth in claim 7, further comprising a connection member on the exposed portion of the redistributed interconnection.

9. The semiconductor package as set forth in claim 8, wherein the connection member comprises at least one selected from the group consisting of a solder ball, a solder bump and a bonding wire.

10. The semiconductor package as set forth in claim 8, wherein the interlayer insulating layer further comprises one or more additional cavities under the connection member.

11. The semiconductor package as set forth in claim 10, wherein the additional cavities have a line-shaped configuration, a circular shaped configuration, a regular triangle-shaped configuration or a quadrangle-shaped configuration.

12. A method of fabricating a semiconductor package, comprising:
forming a semiconductor device having a bonding pad;
forming an interlayer insulating layer on the semiconductor device, the interlayer insulating layer defining an opening exposing the bonding pad and having at least one cavity therein; and
forming a redistributed interconnection on the interlayer insulating layer and the exposed bonding pad so as to overlap the cavity.

13. The method as set forth in claim 12, wherein forming the interlayer insulating layer comprises:
forming a first interlayer insulating layer on the semiconductor device, the first interlayer insulating layer including the cavity and having one or more protrusions extending along a direction parallel to an upper surface of the first interlayer insulating layer to reduce an upper width of the cavity;
forming a second interlayer insulating layer on the first interlayer insulating layer to cover the cavity and the protrusions; and
patterning the first and second interlayer insulating layer to form an opening which exposes the bonding pad.

14. The method as set forth in claim 13, wherein forming the first interlayer insulating layer comprises:
forming an insulating layer on the semiconductor device having the bonding pad;
forming a mask pattern on the insulating layer;
applying an exposure process to the insulating layer using the mask pattern as a photo mask, thereby defining an unexposed region under the mask pattern and an exposed region having a protrusion under edges of the mask pattern;
removing the mask pattern; and
removing the unexposed region of the insulating layer using a development process.

15. The method as set forth in claim 14, wherein a length of the protrusion long a direction parallel to a bottom surface of the mask pattern is controlled according to an exposure energy of the exposure process.

16. The method as set forth in claim 13, wherein the first interlayer insulating layer comprises a negative type photosensitive material layer.

17. The method as set forth in claim 16, wherein the negative type photosensitive material layer comprises at least one selected from the group consisting of a photoresist layer, a photosensitive polyimide (PSPI) layer and a polybenzoxazole (PBO) layer.

18. The method as set forth in claim 13, wherein the second interlayer insulating layer is formed of the same material layer as the first interlayer insulating layer.

19. The method as set forth in claim 12, further comprising:
forming an under barrier metal layer on the interlayer insulating layer and the exposed bonding pad prior to formation of the redistributed interconnection; and
patterning the under barrier metal layer using the redistributed interconnection as an etching mask after formation of the redistributed interconnection, thereby forming an under barrier metal pattern below the redistributed interconnection.

20. The method as set forth in claim 12, further comprising:
forming a passivation layer on the redistributed interconnection and the interlayer insulating layer; and
patterning the passivation layer to form an opening exposing a portion of the redistributed interconnection.

21. The method as set forth in claim 20, further comprising forming a connection member on the exposed portion of the redistributed interconnection.

22. The method as set forth in claim 21, wherein the connection member comprises at least one selected from the group consisting of a solder ball, a solder bump or a bonding wire.

23. The method as set forth in claim 21, wherein the interlayer insulating layer is formed to have one or more additional cavities under the connection member.

24. The method as set forth in claim 23, wherein the additional cavities are formed to have a line-shaped configuration, a circular shaped configuration, a regular triangle-shaped configuration or a quadrangle-shaped configuration.
